(19) United States
(12) Patent Application Publication
(10) Pub. No.: US 2025/0287577 A1
(43) Pub. Date: Sep. 11, 2025

(54) SEMICONDUCTOR DEVICES HAVING INSULATING STRUCTURES

(71) Applicant: Samsung Electronics Co., Ltd., Suwon-si (KR)

(72) Inventors: Jihoon Chang, Suwon-si (KR); Jaewon Na, Suwon-si (KR); Chulkwon Park, Suwon-si (KR); Kyoseon Choi, Suwon-si (KR)

(21) Appl. No.: 18/956,499

(22) Filed: Nov. 22, 2024

(30) Foreign Application Priority Data
Mar. 6, 2024 (KR) 10-2024-0032013

(51) Int. Cl. H10B 12/00

(52) U.S. Cl. CPC H10B 12/488; H10B 12/315; H10B 12/482

(57) ABSTRACT

A semiconductor device, comprising: a bit line structure; back gate structures on the bit line structure; a first channel layer and a second channel layer between the back gate structures; a first word line and a second word line between the first and second channel layers, wherein the first word line is adjacent the first channel layer, and the second word line is adjacent the second channel layer; and an insulating structure on side surfaces of the first and second word lines and upper surfaces of the first and second word lines, wherein the insulating structure includes a core region between the first and second word lines; and an insulating liner between the core region and the first and second word lines, wherein the side surfaces of the first and second word lines face each other, wherein the insulating liner extends to a level higher than those of the first and second word lines.

### CROSS-REFERENCE TO RELATED APPLICATIONS

This application claims benefit of priority to Korean Patent Application No. 10-2024-0032013, filed on Mar. 6, 2024 in the Korean Intellectual Property Office, the inventive concept of which is incorporated herein by reference in its entirety.

### BACKGROUND OF THE INVENTION

The present inventive concept relates to semiconductor devices having insulating structures.

As demand for high performance, high speed, and/or multifunctionality of semiconductor devices increases, a degree of integration of semiconductor devices is increasing. In manufacturing fine-patterned semiconductor devices in response to the trend for high integration of semiconductor devices, it may be required to implement patterns with fine widths or fine spacings.

### SUMMARY OF THE INVENTION

An aspect of the technical problems to be solved by the technical concept of the present inventive concept is to provide a semiconductor device having an insulating structure including an air gap or a low-κ dielectric material disposed between word lines.

According to aspects of the present inventive concept, a semiconductor device, comprising: a bit line structure; back gate structures on the bit line structure; a first channel layer and a second channel layer between the back gate structures in a first direction, wherein the first channel layer and the second channel layer extend in a second direction; a first word line and a second word line between the first channel layer and the second channel layer in the first direction, wherein the first word line is adjacent to the first channel layer, and the second word line is adjacent to the second channel layer; and an insulating structure on a side surface of the first word line, a side surface of the second word line, an upper surface of the first word line, and an upper surface of the second word line, wherein the insulating structure includes a core region between the first word line and the second word line in the first direction; and an insulating liner between the core region and the first word line in the first direction and between the core region and the second word line in the first direction, wherein the side surface of the first word line and the side surface of the second word line face each other in the first direction, wherein the insulating liner extends to a level higher than those of the first word line and the second word line, wherein the first direction is parallel with a lower surface of the bit line structure, and wherein the second direction is perpendicular to the lower surface of the bit line structure.

According to aspects of the present inventive concept, a semiconductor device, comprising: a bit line structure; a channel layer on the bit line structure, wherein the channel layer extends in a first direction; a back gate structure facing a first side surface of the channel layer in a second direction; a word line facing a second side surface of the channel layer that is opposite to the first side surface of the channel layer in the second direction; a gate dielectric layer between the channel layer and the word line in the second direction; and an insulating structure on the word line, wherein the gate dielectric layer includes a vertical portion in contact with a first side surface of the word line and a side surface of the insulating structure, and a horizontal portion in contact with a lower surface of the word line and a lower surface of the insulating structure, wherein the insulating structure includes a core region spaced apart from the word line; and an insulating liner between the core region and a second side surface of the word line in the second direction, and extending between the horizontal portion and the core region in the first direction, wherein the first side surface of the word line is opposite to the second side surface of the word line in the second direction, wherein the first direction is perpendicular to a lower surface of the bit line structure, and wherein the second direction is parallel with the lower surface of the bit line structure.

According to aspects of the present inventive concept, a semiconductor device, comprising: a bit line structure; back gate structures on the bit line structure; a first channel layer and a second channel layer between the back gate structures in a first direction, wherein the first channel layer and the second channel layer extend in a second direction; a first word line and a second word line between the first channel layer and the second channel layer in the first direction, wherein the first word line is adjacent to the first channel layer, and the second word line is adjacent to the second channel layer; an insulating structure in contact with a side surface of the first word line, a side surface of the second word line, an upper surface of the first word line, and an upper surface of the second word line; a gate dielectric layer between the first channel layer and the first word line in the first direction, between the first channel layer and a first upper region of the insulating structure in the first direction, between the second channel layer and the second word line in the first direction, and between the second channel layer and a second upper region of the insulating structure in the first direction; contact patterns electrically connected to the first channel layer and the second channel layer; and an information storage structure on the contact patterns, wherein the insulating structure includes a core region spaced apart from the first word line and second word line; and an insulating liner between the side surface of the first word line and the core region and between the side surface of the second word line and the core region, and extending to a level higher than those of the first word line and the second word line, wherein the core region has a dielectric constant lower than that of silicon oxide, wherein the first upper region of the insulating structure is on the first word line, wherein the second upper region of the insulating structure is on the second word line, wherein the side surface of the first word line and the side surface of the second word line face each other in the first direction, wherein the first direction is parallel with a lower surface of the bit line structure, and wherein the second direction is perpendicular to the lower surface of the bit line structure.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a plan view of a semiconductor device according to an example embodiment;

FIG. 2 is a cross-sectional view taken along line I-I′ of the semiconductor device shown in FIG. 1;

FIG. 3 is an enlarged view of a portion of the semiconductor device shown in FIG. 2;

FIGS. 4 to 19 are cross-sectional views shown according to a process sequence to illustrate a method of manufacturing a semiconductor device according to an example embodiment; and

FIGS. 20 to 25 are cross-sectional views of semiconductor devices according to example embodiments.

### DETAILED DESCRIPTION OF THE INVENTION

Hereinafter, example embodiments of the present inventive concept will be described with reference to the attached drawings.

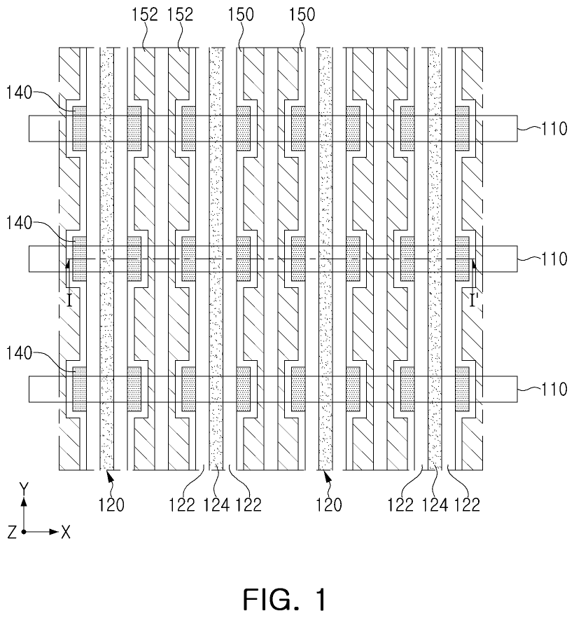

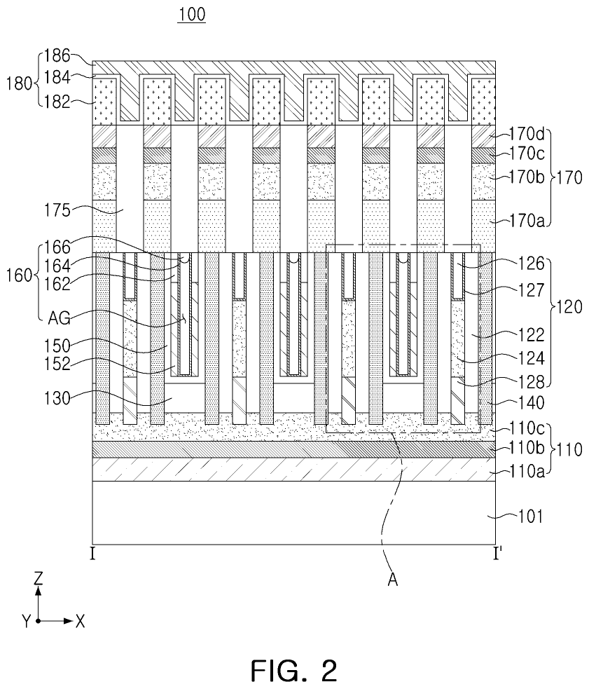

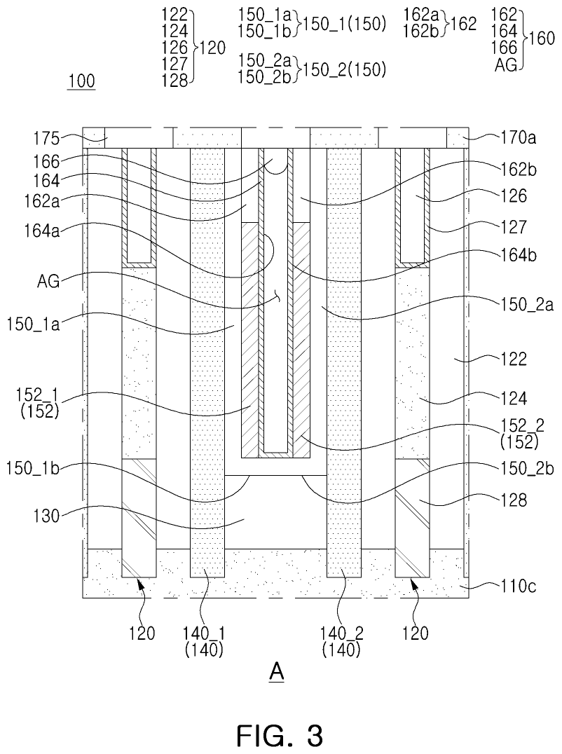

FIG. 1 is a plan view of a semiconductor device according to an example embodiment. FIG. 2 is a cross-sectional view taken along line I-I′ of the semiconductor device shown in FIG. 1. FIG. 3 is an enlarged view of a portion of the semiconductor device shown in FIG. 2. FIG. 3 may correspond to region A of FIG. 2.

Referring to FIGS. 1 to 3, a semiconductor device 100 according to an example embodiment of the present disclosure may include a lower insulating layer 101, a bit line structure 110, a back gate structure 120, a channel layer 140, a word line 152, an insulating structure 160, a contact pattern 170, and an information storage structure 180.

The semiconductor device 100 may include a channel layer 140, a bit line structure 110 electrically connected to the channel layer 140, and a vertical channel transistor comprised of word lines 152 disposed on at least one side of the channel layer 140. It will be understood that when an element or layer is referred to as being “on”, “responsive to”, “connected to”, or “coupled to” another element or layer, it may be directly on, responsive to, connected to, or coupled to the other element or layer, or one or more intervening elements or layers may be present. In contrast, when an element is referred to as being “directly on”, “directly responsive to”, “directly connected to”, or “directly coupled to”, another element, there are no intervening elements present. In addition, “electrical connection” conceptually includes a direct physical connection and an indirect physical connection.

The semiconductor device 100 may be applied to, for example, a cell array of Dynamic Random Access Memory (DRAM), but the present inventive concept is not limited thereto.

The lower insulating layer 101 may include an insulating material such as silicon oxide, silicon nitride, silicon oxynitride (SiON), silicon carbonitride (SiCN), or the like.

The bit line structure 110 may extend in an X-direction on the lower insulating layer 101. In an example embodiment, the bit line structure 110 may be buried within the lower insulating layer 101. The bit line structure 110 may be electrically connected to the channel layer 140.

A plurality of bit line structures 110 may be provided, and the plurality of bit line structures 110 may be spaced apart from each other in a Y-direction and extend in parallel. The X-direction and the Y-direction may be parallel with an upper surface of the lower insulating layer 101 (or a lower surface of the bit line structure 110). The X-direction and the Y-direction may intersect each other. For example, the X-direction and the Y-direction may be perpendicular to each other. A Z-direction may be perpendicular to the upper surface of the lower insulating layer 101 (or the lower surface of the bit line structure 110).

The bit line structure 110 may include, for example, doped polysilicon, metal, conductive metal nitride, metal-semiconductor compound, conductive metal oxide, conductive graphene, carbon nanotube, and/or a combination thereof. For example, the bit line structure 110 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, and/or a combination thereof. In an example embodiment, the bit line structure 110 may include a first conductive pattern 110a, a second conductive pattern 110b, and a third conductive pattern 110c, sequentially stacked on the lower insulating layer 101. The first conductive pattern 110a may include, for example, a metal material such as titanium (Ti), tantalum (Ta), tungsten (W), and aluminum (Al), the second conductive pattern 110b may include, for example, a metal nitride such as titanium nitride (TiN) or a silicide material such as titanium silicide (TiSi), and the third conductive pattern 110c may include, for example, a semiconductor material such as polycrystalline silicon. The third conductive pattern 110c may be a layer doped with impurities. However, depending on example embodiments, materials, the number of layers, and thicknesses of the layers forming the bit line structure 110 may vary. As used herein, the term “and/or” includes any and all combinations of one or more of the associated listed items

The back gate structures 120 may intersect (overlap) the bit line structures 110. For example, the back gate structures 120 may extend in the Y-direction, and may be spaced apart from each other in the X-direction.

The back gate structure 120 may include a back gate dielectric layer 122, a back gate electrode 124, an upper capping layer 126, and a lower capping layer 128. The back gate electrodes 124 may extend in the Y-direction and may be spaced apart from each other in the X-direction. The back gate electrode 124 may serve to remove charges trapped in the channel layer 140. The channel layer 140 may be a floating body, and the back gate electrode 124 may be a structure to supplement the floated channel layer 140 to prevent or minimize performance degradation of the semiconductor device 100 due to a floating body effect of the channel layer 140.

The back gate electrode 124 may include, for example, doped polysilicon, metal, conductive metal nitride, metal-semiconductor compound, conductive metal oxide, graphene, carbon nanotube, and/or a combination thereof. For example, the back gate electrode 124 may comprise doped polysilicon, Al, Cu, Ti, Ta, Ru, W, Mo, Pt, Ni, Co, TiN, TaN, WN, NbN, TiAl, TiAlN, TiAlC, TaAlC, TiSi, TiSiN, TaSi, TaSiN, RuTiN, NiSi, CoSi, IrOx, RuOx, graphene, carbon nanotube, and/or a combination thereof, but the present inventive concept is not limited thereto. The back gate electrode 124 may be formed of a single layer or multiple layers of the above-described materials.

In an example embodiment, the back gate electrode 124 may include (e.g., may be formed of) the same material as the word line 152, but is not limited thereto and may include other materials.

The back gate dielectric layers 122 may extend in the Y-direction along both side surfaces (e.g., opposite side surface in the X-direction) of the back gate electrodes 124. A (vertical) length of the back gate dielectric layer 122 (in the Z-direction) may be greater than a (vertical) length of the back gate electrode 124 (in the Z-direction). For example, an upper surface of the back gate dielectric layer 122 may be located on a level higher than that of an upper surface of the back gate electrode 124, and a lower surface of the back gate dielectric layer 122 may be located on a level higher than that of a lower surface of the back gate electrode 124. The lower surface of the back gate dielectric layer 122 may be in contact with the third conductive pattern 110c. Each of the back gate dielectric layers 122 may include, for example, silicon oxide and/or high-κ dielectric. A high-κ dielectric (material) may refer to a material having a higher dielectric constant than that of silicon oxide. Herein, the level may be a relative location (e.g., distance) from a lower surface of the lower insulating layer 101 (or a lower surface of the bit line structure 110) in a vertical direction (e.g., in the Z-direction). A farther distance from the lower surface of the lower insulating layer 101 (or from the lower surface of the bit line structure 110) may be a higher level. A closer distance from the lower surface of the lower insulating layer 101 (or from the lower surface of the bit line structure 110) may be a lower level.

The upper capping layer 126 may be disposed on the back gate electrode 124. An upper surface of the upper capping layer 126 may be coplanar with an upper surface of the back gate dielectric layer 122. In an example embodiment, the back gate structure 120 may further include a back gate liner 127 on (e.g., covering or overlapping) a lower surface and side surfaces of the upper capping layer 126. The back gate liner 127 may be formed on (conformally along) a side surface of the back gate dielectric layer 122 and an upper surface of the back gate electrode 124. The upper capping layer 126 and the back gate liner 127 may include, for example, silicon oxide, silicon nitride, silicon oxynitride, silicon carbonitride, a low-κ dielectric material, and/or a combination thereof. For example, the upper capping layer 126 and the back gate liner 127 may include silicon nitride. A low-κ dielectric (material) may refer to a material having a lower dielectric constant than that of silicon oxide.

The lower capping layer 128 may be disposed below the back gate electrode 124. For example, the lower capping layer 128 may be on a lower surface of the back gate electrode 124. A lower surface of the lower capping layer 128 may be located on a level lower than that of the lower surface of the back gate dielectric layer 122.

The channel layer 140 may be disposed on (in) the bit line structure 110, and may extend in the vertical direction (e.g., Z-direction). In some embodiments, the channel layer 140 may extend in at least a portion of the bit line structure 110 (e.g., the third conductive pattern 110c). In a plan view, the channel layers 140 may be disposed on both sides (e.g., opposite sides in the X-direction) of the back gate structures 120. The channel layers 140 may be spaced apart from each other in the X- and Y-directions (in a plan view). An upper surface of the channel layer 140 may be coplanar with the upper surface of the back gate structure 120. A lower surface of the channel layer 140 may be in contact with the third conductive pattern 110c and may be located on a level lower than that of the lower surface of the back gate dielectric layer 122. In some embodiments, the lower surface of the back gate dielectric layer 122 may be in contact with the upper surface of the bit line structure 110 (e.g., the upper surface of the third conductive pattern 110c).

Each of the channel layers 140 may include a first source/drain region in contact with the bit line structure 110 and a second source/drain region connected (e.g., electrically connected) to the contact pattern 170. In an example embodiment, the first and second source/drain regions may have an N-type conductivity type.

In an example embodiment, the channel layers 140 may include a monocrystalline semiconductor material. The monocrystalline semiconductor material may include a group IV semiconductor, a group III-V compound semiconductor, and/or a group II-VI compound semiconductor, and may be, for example, a single crystal including silicon, silicon carbide, germanium, and/or silicon-germanium.

However, depending on example embodiments, the channel layers 140 may include a polycrystalline semiconductor material layer, an oxide semiconductor material layer such as Indium Gallium Zinc Oxide (IGZO), and/or a two-dimensional material layer such as MoS₂, or the like.

The oxide semiconductor material layer may include indium gallium zinc oxide (IGZO). However, the example embodiment thereof is not limited thereto. For example, the oxide semiconductor material layer may include Indium Tungsten Oxide (IWO), Indium Tin Gallium Oxide (ITGO), Indium Aluminum Zinc Oxide (IAZO), Indium Gallium Oxide (IGO), Indium Tin Zinc Oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and/or indium gallium silicon oxide (InGaSiO).

The two-dimensional material layer may include, for example, a TMD material layer (Transition Metal Dichalcogenide material layer), a black phosphorous material layer, and/or a hBN material layer (hexagonal Boron-Nitride material layer) which may have semiconductor properties. For example, the two-dimensional material layer may include BiOSe, Crl, WSe2, MoS₂, TaS, WS, SnSe, ReS, β-SnTe, MnO, AsS, P(black), InSe, h-BN, GaSe, GaN, SrTiO, MXene, and/or Janus 2D materials which may form two-dimensional materials.

The word lines 152 may be disposed on the bit line structure 110, and may be disposed on both sides (e.g., opposite sides in the X-direction) of the back gate structure 120. The word lines 152 may be spaced apart from each other in the X-direction. In a plan view, the word line 152 may extend around (e.g., surround) at least a portion of channel layers 140, and the channel layers 140 may be disposed between the back gate structure 120 and the word line 152. The word line 152 may include a first word line 152_1 and a second word line 152_2 disposed between two adjacent back gate structures 120 (in the X-direction). The channel layer 140 may include a first channel layer 140_1 and a second channel layer 140_2 disposed between the two adjacent back gate structures 120 (in the X-direction), and the first word line 152_1 and the second word line 152_2 may be disposed between the first channel layer 140_1 and the second channel layer 140_2 (in the X-direction). The first word line 152_1 may be adjacent the first channel layer 140_1, and the second word line 152_2 may be adjacent the second channel layer 140_2.

The word line 152 may include, for example, doped polysilicon, metal, conductive metal nitride, metal-semiconductor compound, conductive metal oxide, conductive graphene, carbon nanotube, and/or a combination thereof. For example, the word line 152 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, and/or a combination thereof, but is not limited thereto. The word line 152 may include a single layer or multiple layers of the materials described above.

The semiconductor device 100 may further include a gate dielectric layer 150 and an insulating structure 160. The gate dielectric layer 150 may be disposed between the word line 152 and the channel layer 140 (in the X-direction) and may have a U-shape or a similar shape in a cross-sectional view. For example, the gate dielectric layer 150 may be disposed below (on) the lower surface of the insulating structure 160 and may (include portions that) extend between the first channel layer 140_1 and the first word line 152_1 and between the second channel layer 140_2 and the two word lines 152_2 (in the X-direction and/or the Y-direction). In some embodiments, in a plan view, the gate dielectric layer 150 may include portions that extend between the back gate structure 120 and the word line 152 (the first word line 152_1 or the second word line 152_2) without the channel layer 140 (the first channel layer 140_1 or the second channel layer 140_2) therebetween.

The gate dielectric layer 150 may include a first gate dielectric layer 150_1 and a second gate dielectric layer 150_2. The first gate dielectric layer 150_1 may include a first vertical portion 150_1a and a first horizontal portion 150_1b. The first vertical portion 150_1a may include at least a portion that extends in the Z-direction between the first channel layer 140_1 and the first word line 152_1. In some embodiments, the first vertical portion 150_1a may include a portion that extends in the Z-direction between the first channel layer 140_1 and a first gate capping layer 162a (to be described later) on the first word line 152_1. For example, the first vertical portion 150_1a may be in contact with a side surface of the first channel layer 140_1, a side surface of the first word line 152_1, and/or a side surface of the first gate capping layer 162a. In some embodiments, an upper surface of the first vertical portion 150_1a may be a portion of an upper (e.g., the uppermost) surface of the gate dielectric layer 150 (e.g., a portion of an upper (e.g., the uppermost) surface of the first gate dielectric layer 150_1). A lower surface of the first vertical portion 150_1a may be a portion of a lower surface of the gate dielectric layer 150 (e.g., a portion of a lower surface of the first gate dielectric layer 150_1) or in contact with the first horizontal portion 150_1b. The first horizontal portion 150_1b may extend in the X-direction between the first channel layer 140_1 and a second horizontal portion 150_2b (to be described later) or between the first vertical portion 150_1a and the second horizontal portion 150_2b. The first horizontal portion 150_1b may include a portion that is disposed between the first word line 152_1 and the bit line structure 110 (or a lower insulating pattern 130 (to be described later)) in the Z-direction. A lower surface of the first horizontal portion 150_1b may be a portion of the lower surface of the gate dielectric layer 150 (e.g., a portion of the lower surface of the first gate dielectric layer 150_1). In some embodiments, the first horizontal portion 150_1b may be in contact with the lower surface of the first word line 152_1 and the lower surface of the insulating structure 160 (e.g., a lower surface of an insulating liner 164, which will be described later) The second gate dielectric layer 150_2 may include a second vertical portion 150_2a and a second horizontal portion 150_2b. The second vertical portion 150_2a may include at least a portion that extends in the Z-direction between the second channel layer 140_2 and the second word line 152_2. In some embodiments, the second vertical portion 150_2a may include a portion that extends in the Z-direction between the second channel layer 140_2 and a second gate capping layer 162b (to be described later) on the second word line 152_2. For example, the second vertical portion 150_2a may be in contact with a side surface of the second channel layer 140_2, a side surface of the second word line 152_2, and/or a side surface of the second gate capping layer 162b. In some embodiments, an upper surface of the second vertical portion 150_2a may be a portion of an upper (e.g., the uppermost) surface of the gate dielectric layer 150 (e.g., a portion of an upper (e.g., the uppermost) surface of the second gate dielectric layer 150_2). A lower surface of the second vertical portion 150_2a may be a portion of a lower surface of the gate dielectric layer 150 (e.g., a portion of a lower surface of the second gate dielectric layer 150_2) or in contact with the second horizontal portion 150_2b. The second horizontal portion 150_2b may extend in the X-direction between the second channel layer 140_2 and the first horizontal portion 150_1b or between the second vertical portion 150_2a and the first horizontal portion 150_1b. The second horizontal portion 150_2b may include a portion that is disposed between the second word line 152_2 and the bit line structure 110 (or the lower insulating pattern 130) in the Z-direction. A lower surface of the second horizontal portion 150_2b may be a portion of the lower surface of the gate dielectric layer 150 (e.g., a portion of the lower surface of the second gate dielectric layer 150_2). In some embodiments, the second horizontal portion 150_2b may be in contact with the lower surface of the second word line 152_2 and the lower surface of the insulating structure 160 (e.g., the lower surface of the insulating liner 164, which will be described later). In some embodiments, an upper surface (e.g., the uppermost surface) of the gate dielectric layer 150 may be coplanar with an upper surface of the channel layer 140. The first vertical portion 150_1a, the first horizontal portion 150_1b, the second vertical portion 150_2a, and the second horizontal portion 150_2b may form an integrated unitary structure (the gate dielectric layer 150) having no visible boundaries therebetween.

In an example, each of the gate dielectric layers 150 may be a tunnel dielectric layer not including an information storage layer. For example, each of the gate dielectric layers 150 may include, for example, silicon oxide and/or a high-κ dielectric material. The high-κ dielectric material may include metal oxide and/or metal oxynitride. For example, the high-κ dielectric material may include HfO₂, HfSiO, HfSiON, HfTaO, HfTiO, HfZrO, ZrO₂, Al₂O₃, and/or a combination thereof, but the present disclosure is not limited thereto. Each of the gate dielectric layers 150 may be formed of a single layer or multiple layers of the above-described materials.

In another example, each of the gate dielectric layers 150 may include an information storage layer and a dielectric layer. For example, each of the gate dielectric layers 150 may have polarization characteristics depending on an electric field and may include a ferroelectric layer that may have remnant polarization due to a dipole even in the absence of an external electric field. Data may be recorded using the polarization state within the ferroelectric layer. Accordingly, each of the gate dielectric layers 150 may include a ferroelectric layer, which may be referred to as an information storage layer. The ferroelectric layer, which may be the information storage layer, may include, for example, an Hf-based compound, a Zr-based compound, and/or an Hf-Zr-based compound. For example, the Hf-based compound may include a HfO-based ferroelectric material, the Zr-based compound may include a ZrO-based ferroelectric material, and the Hf-Zr-based compound may include a hafnium zirconium oxide (HZO)-based ferroelectric material. The ferroelectric layer, which may be the information storage layer, may include a ferroelectric material doped with impurities, for example, C, Si, Mg, Al, Y, N, Ge, Sn, Gd, La, Sc, and/or Sr. For example, the ferroelectric layer, which may be the information storage layer, may include a material in which HfO₂, ZrO₂, and/or HzrO is doped with impurities such as C, Si, Mg, Al, Y, N, Ge, Sn, Gd, La, Sc, and/or Sr.

In the gate dielectric layers 150, the information storage layer is not limited to the types of the above-described materials, and may include a material that can store information.

In a cross-sectional view, the insulating structure 160 may be disposed between the (adjacent) back gate structures 120 (in the X-direction). For example, (each of) the insulating structures 160 may include at least a portion that extends in the Y-direction between adjacent word lines 152 (in the X-direction) and may be spaced apart from each other in the X-direction. For example, at least a portion of the insulating structure 160 may extend in the Y-direction between the first word line 152_1 and the second word line 152_2 in the X-direction. The insulating structure 160 may be disposed on the word lines 152 and may extend between the word lines 152. For example, the insulating structure 160 may contact side surfaces of the first and second word lines 152_1 and 152_2 facing each other (in the X-direction) and upper surfaces of the first and second word lines 152_1 and 152_2.

In an example embodiment, the insulating structure 160 may include a core region, a gate capping layer 162, an insulating liner 164, and a capping pattern 166. The core region may include a region disposed between the first and second word lines 152_1 and 152_2 (in the X-direction). The gate capping layers 162 may overlap the word lines 152 in a vertical direction (e.g., in the Z-direction), and may contact the gate dielectric layers 150. The gate capping layers 162 may include a first gate capping layer 162a on (e.g., overlapping in the Z-direction) the first word line 152_1 and a second gate capping layer 162b on (e.g., overlapping in the Z-direction) the second word line 152_2. In some embodiments, the core region may include a region disposed between the first gate capping layer 162a and the second gate capping layer 162b.

The insulating liner 164 may extend between the gate capping layers 162 (e.g., between the first gate capping layer 162a and the second gate capping layer 162b) and between the word lines 152 (e.g., between the first word line 152_1 and the second word line 152_2). The insulating liner 164 may be disposed between the core area and the first word line 152_1, and may extend to a level higher than that of the first word line 152_1. The insulating liner 164 may be also disposed between the core region and the second word line 152_2, and may extend to a level higher than that of the second word line 152_2. For example, the insulating liner 164 may have a U-shape in a cross-sectional view, and may contact side surfaces of the gate capping layers 162 (e.g., the first gate capping layer 162a and the second gate capping layer 162b), side surfaces of the word lines 152 (e.g., the first word line 152_1 and the second word line 152_2), and the gate dielectric layers 150 (e.g., the first horizontal portion 150_1b and the second horizontal portion 150_2b). The insulating liner 164 may extend from between the core region and the first word line 152_1 to between the core region and the first gate capping layer 162a. The insulating liner 164 may also extend from between the core region and the second word line 152_2 to between the core region and the second gate capping layer 162b. For example, the insulating liner 164 may extend in the Z-direction between the core region and the first gate capping layer 162a and between the core region and the first word line 152_1. The insulating liner 164 may extend in the Z-direction between the core region and the second gate capping layer 162b and between the core region and the second word line 152_2. The insulating liner 164 may extend from between the core region and the first word line 152_1 and from between the core region and the second word line 152_2 to between the core region and the gate dielectric layer 150. For example, the insulating liner 164 may extend between the first word line 152_1 and the second word line 152_2 in the X-direction between the core region and the gate dielectric layer 150 (e.g., the first horizontal portion 150_1b and/or the second horizontal portion 150_2b) in the Z-direction.

The capping pattern 166 may be disposed between the gate capping layers 162 (e.g., between the first gate capping layer 162a and the second gate capping layer 162b in the X-direction) on the core region, and may be in contact with the insulating liner 164. For example, the capping pattern 166 may contact an upper region of an inner surface 164a of the insulating liner 164. An outer surface 164b of the insulating liner 164 may be in contact with the word lines 152 (e.g., the first word line 152_1 and the second word line 152_2) and the gate capping layers 162 (e.g., the first gate capping layer 162a and the second gate capping layer 162b). The insulating liner 164 may extend between the capping pattern 166 and the first gate capping layer 162a and between the capping pattern 166 and the second gate capping layer 162b. A lower surface of the insulating liner 164 may be in contact with the gate dielectric layer 150. A thickness of the insulating liner 164 may be greater than 0 Å and less than or equal to 10 Å. In an example embodiment, a lower surface of the capping pattern 166 may be convex (toward the core region in the Z-direction). Herein an upper region of an element may refer to a portion of the region of the element disposed farther than the central portion of the element from the lower surface of the lower insulating layer 101 in the Z-direction. A lower region of an element may refer to a portion of the region of the element disposed closer than the central portion of the element to the lower surface of the lower insulating layer 101 in the Z-direction.

The gate capping layer 162, the insulating liner 164, and the capping pattern 166 may include, for example, silicon oxide, silicon nitride, silicon oxynitride, silicon carbonitride, low-κ dielectric material, and/or a combination thereof. In some embodiments, the insulating liner 164 may include the same material as the back gate liner 127, for example, silicon nitride.

In an example embodiment, the insulating structure 160 may further include an air gap (AG) therein. For example, the core region may include (may be) an air gap AG. The air gap AG may refer to an empty (substantially empty) space or a space including (filled with) air and/or gas. The air gap AG may be defined by the insulating liner 164 and the capping pattern 166. For example, a lateral limit (in the X-direction) and a lower limit (in the Z-direction) of the air gap AG may be defined by the insulating liner 164, and an upper limit (in the Z-direction) of the air gap AG may be defined by the capping pattern 166. For example, the air gap AG may be surrounded by the insulating liner 164 and the capping pattern 166. In some example embodiments, the insulating structure 160 may include a low-κ dielectric material having a lower dielectric constant than silicon oxide therein. For example, the core region may include the low-κ dielectric material.

Since the insulating structure 160 (e.g., the core region) includes an air gap AG or a low-κ dielectric material therein, a dielectric constant of the core region may be lower than a dielectric constant of silicon oxide, and capacitance between the adjacent first word line 152_1 and the second word line 152_2 may be reduced. Accordingly, when one of the first word line 152_1 and the second word line 152_2 operates, a change in voltages of another word line may be reduced or prevented. That is, coupling noise between the adjacent word lines 152 (e.g., the first word line 152_1 and the second word line 152_2) and coupling noise between the adjacent channel layers 140 (e.g., the first channel layer 140_1 and the second channel layer 140_2) may be reduced. Therefore, when the semiconductor device 100 operates, leakage current may be prevented from increasing in an unselected transistor adjacent to the selected transistor. In addition, when an air gap AG or low-κ dielectric material is included therein, the capacitance of the insulating structure 160 is reduced, so a distance between the first word line 152_1 and the second word line 152_2 can be reduced, so that the semiconductor device 100 can be implemented with smaller design rules.

The gate capping layer 162, the insulating liner 164, and the capping pattern 166 may include, for example, silicon oxide, silicon nitride, silicon oxynitride, silicon carbonitride, low-κ dielectric material, and/or a combination thereof. For example, the gate capping layer 162, the insulating liner 164, and the capping pattern 166 may include silicon nitride.

The semiconductor device 100 may further include lower insulating patterns 130 disposed between the channel layers 140 (in the X-direction) and below the word lines 152. The lower insulating patterns 130 may contact an upper surface of the third conductive pattern 110c, side surfaces of the channel layers 140, and lower surfaces of the gate dielectric layers 150. Lower surfaces of the lower insulating patterns 130 may be located on a level higher than that of lower surfaces of the channel layers 140. The lower insulating pattern 130 may be on the third conductive pattern 110c, and the gate dielectric layer 150 may be on the lower insulating pattern 130. The lower insulating patterns 130 may include, for example, silicon oxide, silicon nitride, silicon oxynitride, silicon carbonitride, low dielectric constant, and/or a combination thereof. For example, the lower insulating patterns 130 may include silicon oxide.

The contact patterns 170 may be disposed on the channel layers 140 and may be electrically connected to the channel layers 140. The contact patterns 170 may electrically connect the channel layers 140 and the information storage structure 180.

Lower surfaces of the contact patterns 170 are shown as being in contact with the channel layer 140 and the gate dielectric layer 150. However, according to example embodiments, the lower surfaces of the contact patterns 170 may also be in contact with the insulating structure 160 and/or the upper capping layer 126. The lower surface of the contact patterns 170 may be in contact with the back gate structure 120. In some embodiments, the contact patterns 170 may overlap with the back gate structure 120, the channel layer 140, the gate dielectric layer 150, and/or the insulating structure 160 in the Z-direction.

The contact patterns 170 may include a conductive material, for example, doped monocrystalline silicon, doped polycrystalline silicon, metal, conductive metal nitride, metal-semiconductor compound, conductive metal oxide, conductive graphene, carbon nanotubes, and/or a combination thereof. In an example embodiment, the contact patterns 170 may include first, second, third, and fourth contact layers 170a, 170b, 170c, and 170d, sequentially stacked. For example, the first contact layer 170a may include undoped polycrystalline silicon, the second contact layer 170b may include doped polycrystalline silicon, the third contact layer 170c may include a silicide material, and the fourth contact layer 170d may include a metal. However, depending on example embodiments, the number of layers and type of materials of the contact patterns 170 may vary.

The semiconductor device 100 may further include upper insulating patterns 175 disposed between the contact patterns 170 (in the X-direction). Each of the upper insulating patterns 175 may extend vertically (in the Z-direction) and may contact the insulating structure 160 and/or the upper capping layer 126. The upper insulating patterns 175 may spatially separate the contact patterns 170 and electrically insulate the same. For example, the upper insulating patterns 175 and the contact patterns 170 may be alternately arranged in the X-direction.

The information storage structures 180 may include first electrodes 182 electrically connected to the contact patterns 170, second electrodes 186 on (overlapping or covering) the first electrodes 182, and a dielectric layer 184 between the first electrodes 182 and the second electrodes 186.

In an example embodiment, the information storage structures 180 may be capacitors storing information in a DRAM. For example, the dielectric layer 184 of the information storage structures 180 may be a capacitor dielectric layer of a DRAM, and the dielectric layer 184 may include a high-κ dielectric material, silicon oxide, silicon nitride, silicon oxynitride, and/or a combination thereof.

Depending on example embodiments, the information storage structures 180 may be structures storing DRAM and other memory information. For example, the dielectric layer 184 of the information storage structure 180 may be a capacitor dielectric layer of a ferroelectric memory (FeRAM). In this case, the dielectric layer 184 may be a ferroelectric layer that can record data using a polarization state. In example embodiments, the dielectric layer 184 may include a lower dielectric layer including silicon oxide and/or a high-κ dielectric and a ferroelectric layer disposed on the lower dielectric layer.

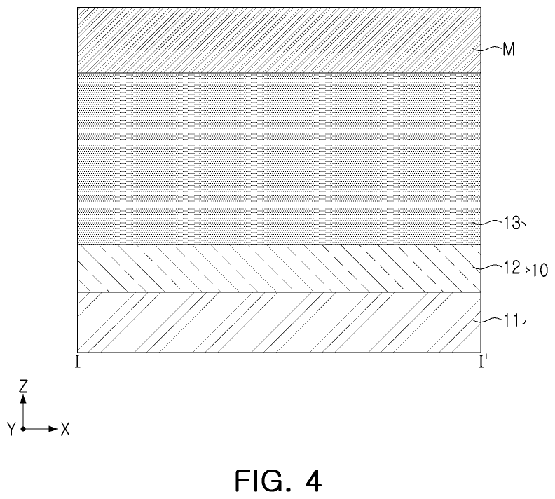

FIGS. 4 to 19 are cross-sectional views shown according to a process sequence to illustrate a method of manufacturing a semiconductor device according to an example embodiment.

Referring to FIG. 4, a mask layer M may be formed on the semiconductor substrate 10. In an example embodiment, the semiconductor substrate 10 may be a silicon on insulator (SOI) substrate. The semiconductor substrate 10 may include a lower semiconductor layer 11, an insulating layer 12, and an upper semiconductor layer 13. For example, the upper and lower semiconductor layers 11 and 13 may include monocrystalline silicon. In some example embodiments, the semiconductor substrate 10 may be a bulk silicon substrate.

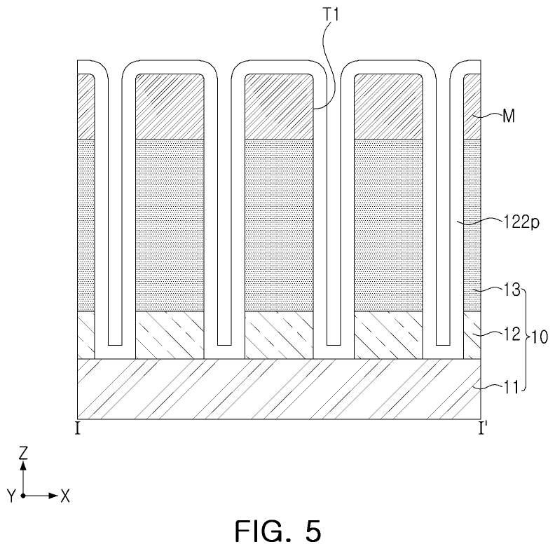

Referring to FIG. 5, back gate trenches T1 may be formed within the semiconductor substrate 10. The back gate trenches T1 may vertically penetrate (extend in the Z-direction) the mask layer M, the upper semiconductor layer 13, and the insulating layer 12, and expose an upper surface of the lower semiconductor layer 11. The back gate trenches T1 may extend in the Y-direction and may be spaced apart from each other in the X-direction.

A dielectric material layer 122p may be formed conformally along inner walls of the back gate trenches T1. The dielectric material layer 122p may be on (e.g., cover) the side surfaces of the mask layer M, the upper semiconductor layer 13, and the insulating layer 12, and may be on (e.g., cover) the upper surface of the lower semiconductor layer 11.

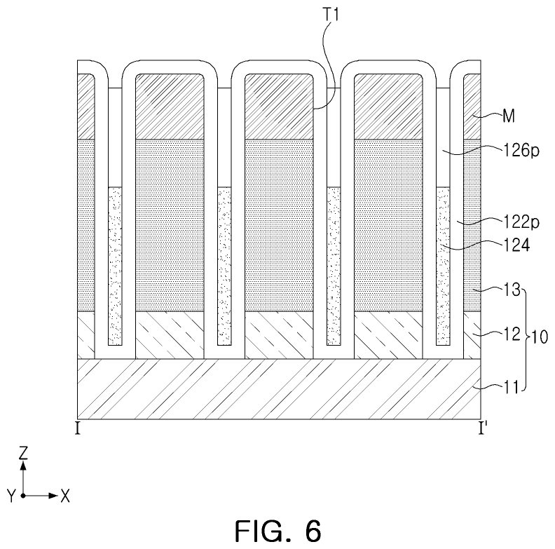

Referring to FIG. 6, a back gate electrode 124 and a preliminary capping layer 126p may be formed on the dielectric material layer 122p. The back gate electrode 124 may fill lower portions of the back gate trenches T1, and the preliminary capping layer 126p may be disposed on the back gate electrode 124 (may fill upper portions of the back gate trenches T1). In an example embodiment, the back gate electrode 124 may include metal nitride, such as TiN, or polycrystalline silicon.

The preliminary capping layer 126p may include, for example, silicon oxide, silicon nitride, silicon oxynitride, and/or a combination thereof. In an example embodiment, the preliminary capping layer 126p may include silicon oxide.

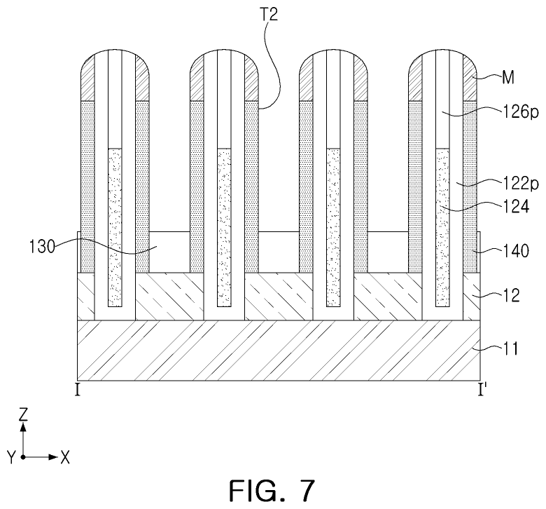

Referring to FIG. 7, gate trenches T2 may be formed within the upper semiconductor layer 13. The gate trenches T2 may be formed by anisotropically etching the upper semiconductor layer 13 to expose the upper surface of the insulating layer 12. The gate trenches T2 may extend in the Y-direction and may be spaced apart from each other in the X-direction. The upper semiconductor layer 13 patterned by the etching process of the gate trenches T2 may be referred to as a channel layer 140. In some embodiments, the back gate trenches T1 and the gate trenches T2 may be spaced apart from each other in the X-direction. For example, the back gate trenches T1 and the gate trenches T2 may be alternately arranged in the X-direction.

After the etching process of the gate trenches T2, the channel layer 140 may be further patterned in the X-direction. As shown in FIG. 1, the patterned channel layers 140 may be spaced apart from each other in the Y-direction along the back gate electrodes 124.

Lower insulating patterns 130 may be formed between the channel layers 140. The lower insulating patterns 130 may be on (may contact) lower regions of the side surfaces of the channel layers 140. The lower insulating patterns 130 may include, for example, silicon oxide, silicon nitride, silicon oxynitride, and/or a combination thereof. In an example embodiment, the lower insulating patterns 130 may include silicon oxide.

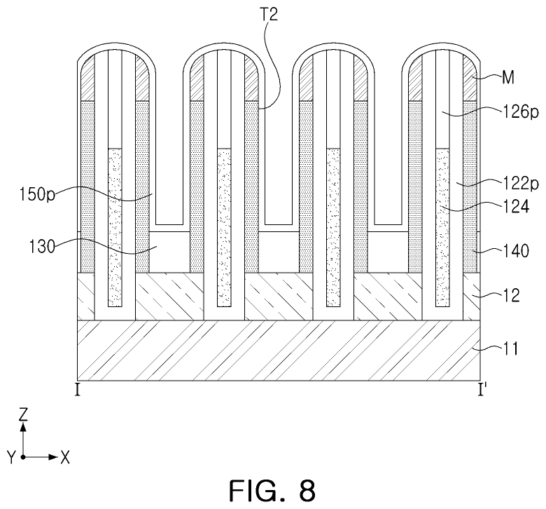

Referring to FIG. 8, a dielectric material layer 150p may be formed conformally along inner walls of the gate trenches T2. The dielectric material layer 150p may be on (e.g., cover) the mask layer M (e.g., a side surface and an upper surface (an upper end) of the mask layer M), the dielectric material layer 122p (e.g., an upper surface (an upper end) of the dielectric material layer 122p), the preliminary capping layer 126p (e.g., an upper surface (an upper end) of the preliminary capping layer 126p), the lower insulating pattern 130 (e.g., an upper surface of the lower insulating pattern 130), and the channel layer 140 (e.g., a side surface of the channel layer 140).

Referring to FIG. 9, word lines 152, a sacrificial layer 160p, and a gate capping layer 162 may be formed. The word lines 152 may be formed on the dielectric material layer 150p within the gate trenches T2. For example, the word line 152 may be on a side surface and an upper surface of the dielectric material layer 150p exposed by the gate trenches T2. The word lines 152 may be formed by depositing a conductive material on the dielectric material layer 150p, and anisotropically etching the conductive material. As shown in FIG. 1, the word lines 152 may extend in the Y-direction along the back gate electrodes 124, and may be spaced apart from each other in the X-direction.

The gate capping layer 162 may be formed on the word lines 152. In an example embodiment, the gate capping layer 162 may be formed by forming an insulating material on the conductive material, and anisotropically etching the insulating material together with the conductive material. For example, the gate capping layer 162 may be on an upper surface of the word line 152 and a side surface of the dielectric material layer 150p.

The sacrificial layer 160p may be formed between the word lines 152 and the gate capping layers 162 (in the X-direction). The sacrificial layer 160p may include a material having etch selectivity with that of the gate capping layer 162. For example, the gate capping layer 162 may include silicon nitride, and the sacrificial layer 160p may include silicon oxide. In some example embodiments, the sacrificial layer 160p may include the same material as the gate capping layer 162 and may be formed integrally with the gate capping layer 162.

A planarization process may be performed to remove the mask layer M and expose upper surfaces of the channel layers 140. Upper portions of the dielectric material layer 122p and the dielectric material layer 150p may be removed to form a back gate dielectric layer 122 and a gate dielectric layer 150, respectively.

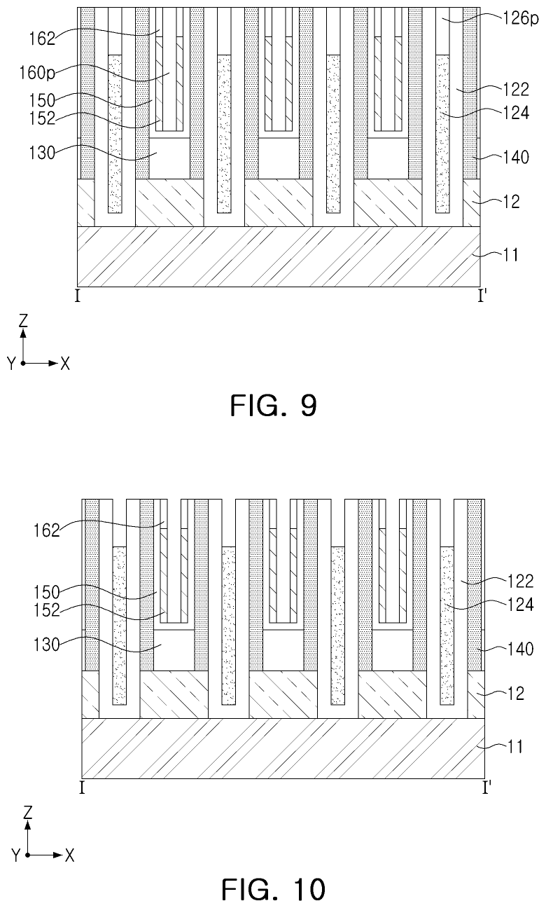

Referring to FIG. 10, the sacrificial layer 160p may be removed and the word lines 152 may be exposed. For example, the sacrificial layer 160p between the gate capping layers 162 may be selectively removed by a wet etching process. In an example embodiment, the preliminary capping layer 126p may also be removed through the etching process, and the back gate electrodes 124 may be exposed. In some example embodiments, the preliminary capping layer 126p may include a material having etch selectivity with the sacrificial layer 160p, and the material may not be removed. In an example embodiment, upper portions of the back gate dielectric layer 122 and the gate dielectric layer 150 may be (partially) etched.

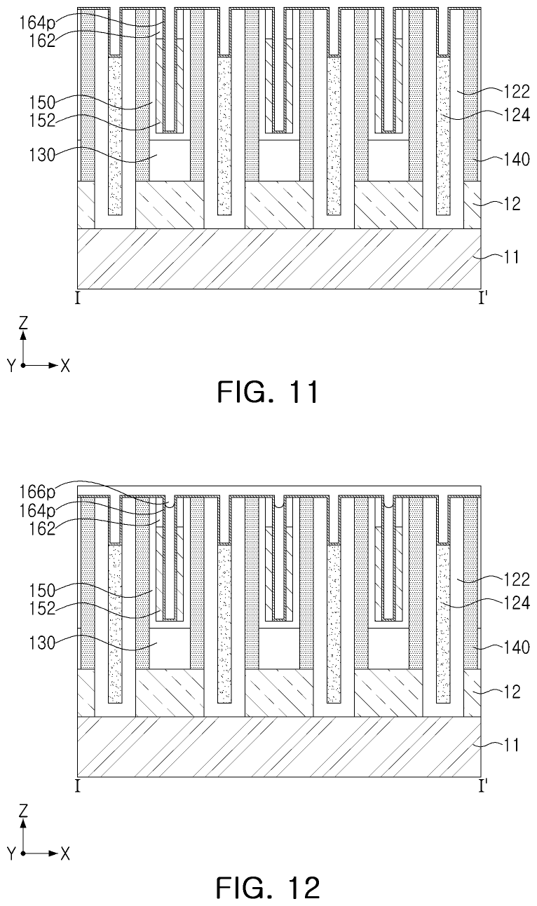

Referring to FIG. 11, a liner material layer 164p may be formed. The liner material layer 164p may be on (e.g., cover) a side surface (and/or an upper surface) of the back gate dielectric layer 122, and an upper surface of the back gate electrode 124. The liner material layer 164p may also be on (e.g., cover) a side surface of the word line 152, a side surface (and/or an upper surface) of the gate capping layer 162, and an upper surface of the gate dielectric layer 150. The liner material layer 164p may include, for example, silicon nitride and may cover the word lines 152 to prevent the word lines 152 from being oxidized. An upper surface of an element may include an uppermost surface of the element and an upper surface of the element lower than the uppermost surface of the element. For example, the liner material layer 164p may be on the uppermost surface of the gate dielectric layer 150 and on an upper surface of the gate dielectric layer 150 lower than the uppermost surface of the gate dielectric layer 150.

Referring to FIG. 12, a capping material layer 166p may be formed. The capping material layer 166p may be on (e.g., cover) upper surfaces of the channel layers 140, and (at least partially) fill a space between the back gate dielectric layers 122. A portion of the capping material layer 166p may be disposed between the gate capping layers 162, and may define an air gap AG. The capping material layer 166p may partially fill a space between the adjacent gate capping layers 162 in the X-direction. For example, the air gap AG may be disposed between adjacent word lines 152 (in the X-direction), and between the capping material layer 166p (which will become the capping pattern 166 in later processes) and the liner material layer 164p (which will become the insulating liner 164) (in the Z-direction).

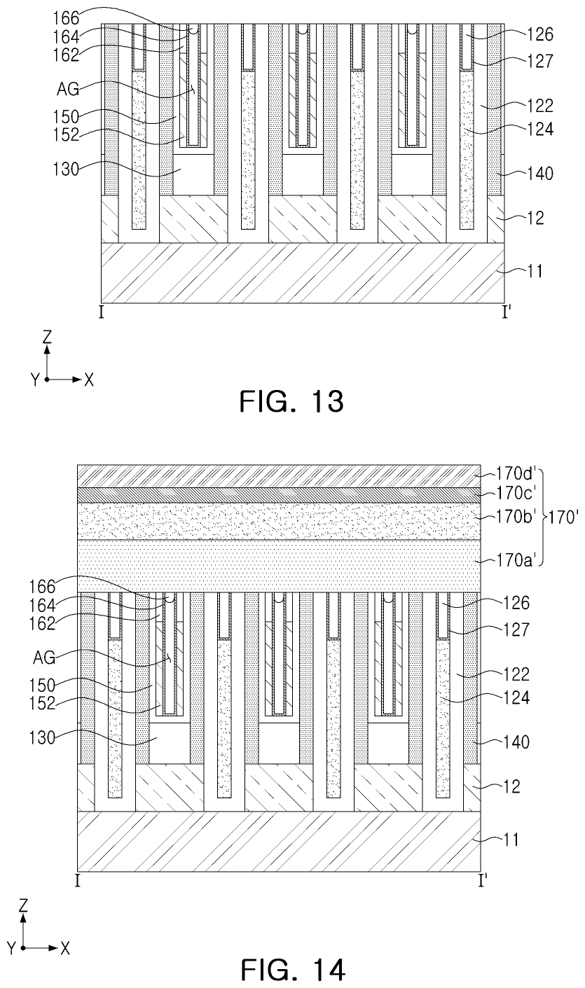

Referring to FIG. 13, the liner material layer 164p and the capping material layer 166p may be etchbacked to form an insulating liner 164 and a capping pattern 166. The capping pattern 166 may define an upper limit of the air gap AG, and the insulating liner 164 may define a lateral limit (in the X-direction) and a lower limit of the air gap AG. A portion of the capping material layer 166p (at least partially) filling the space between the back gate dielectric layers 122 (e.g., between the back gate liner 127) may be referred to as an upper capping layer 126. The upper surfaces of the channel layers 140 may be exposed through the etch-back process.

Referring to FIG. 14, a contact material layer 170′ may be formed on the channel layers 140. The contact material layer 170′ may include a first contact material layer 170a′, a second contact material layer 170b′, a third contact material layer 170c′, and a fourth contact material layer 170d′, sequentially stacked.

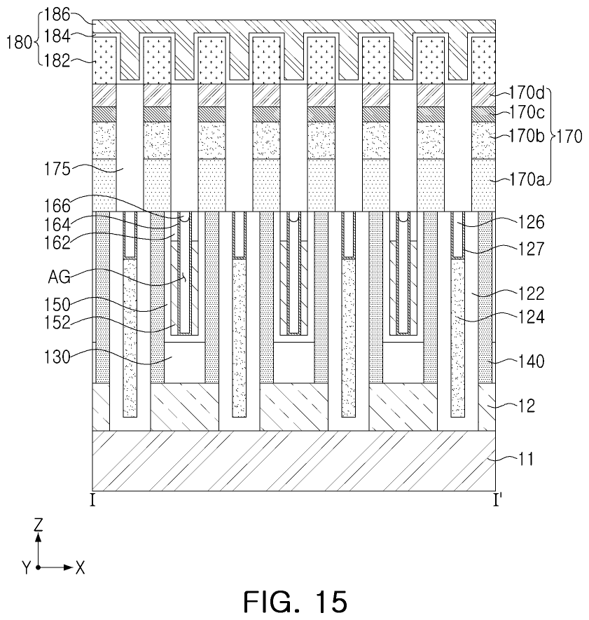

Referring to FIG. 15, the contact material layer 170 may be patterned to form a contact pattern 170. The contact pattern 170 may include a first contact pattern 170a, a second contact pattern 170b, a third contact pattern 170c, and a fourth contact pattern 170d, sequentially stacked. The contact pattern 170 may be electrically connected to the channel layer 140.

Upper insulating patterns 175 may be formed between the contact patterns 170. The upper insulating patterns 175 may be formed by patterning the contact material layer 170′ and filling the same with an insulating material. The upper insulating patterns 175 may electrically separate the contact patterns 170 from each other. For example, the upper insulating patterns 175 and the contact patterns 170 may be alternately arranged in the X-direction.

An information storage structure 180 including first electrodes 182, a dielectric layer 184, and a second electrode 186 may be formed on the contact patterns 170. The first electrodes 182 may contact the fourth contact patterns 170d of the contact patterns 170.

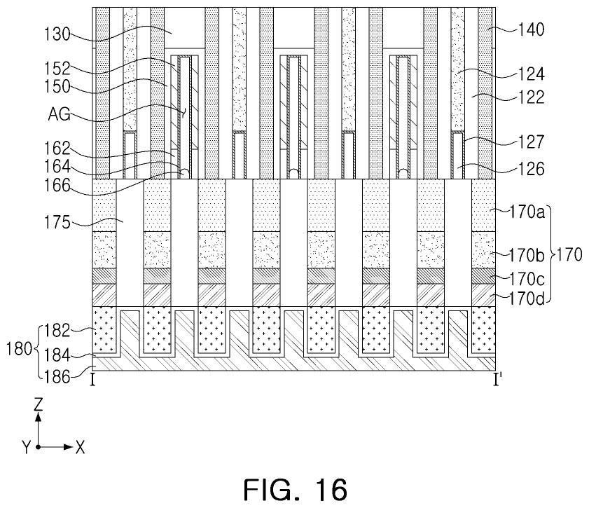

Referring to FIG. 16, the resulting structure of FIG. 15 may be turned over so that the information storage structure 180 faces downwardly of the lower semiconductor layer 11 and a grinding process may be performed. Through the grinding process, the lower semiconductor layer 11 and the insulating layer 12 may be removed, and the lower insulating pattern 130 and the channel layer 140 may be exposed. The back gate dielectric layer 122 and the back gate electrode 124 may also be partially etched to be coplanar with the channel layer 140.

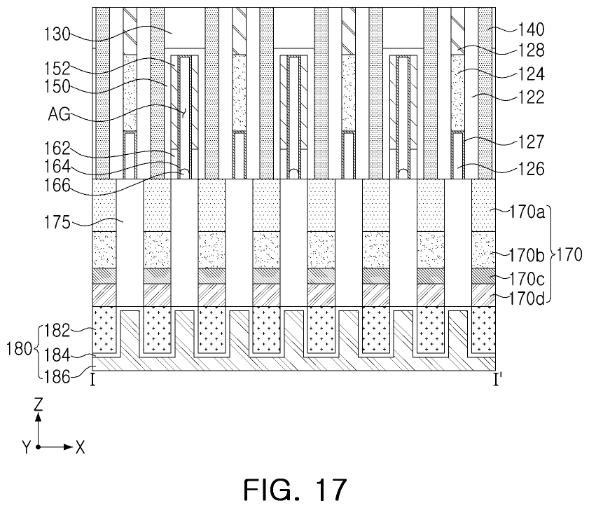

Referring to FIG. 17, a portion of the back gate electrode 124 may be removed, and a lower capping layer 128 may be formed in a space in which the portion of the back gate electrode 124 has been removed. The back gate electrode 124 may be disposed between the upper capping layer 126 and the lower capping layer 128 and may not be exposed.

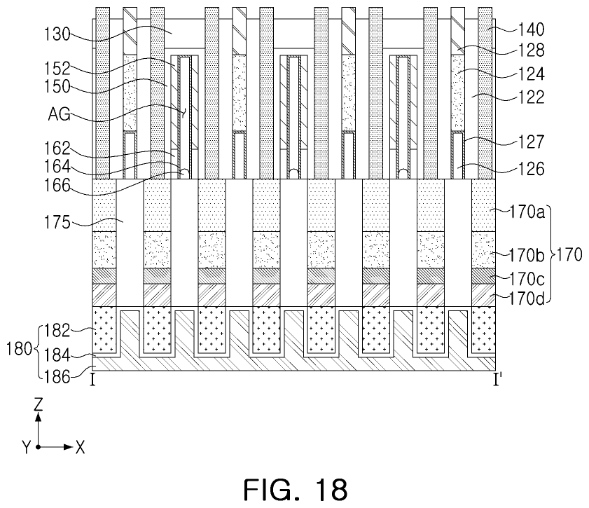

Referring to FIG. 18, a cleaning process may be performed. Through the cleaning process, an oxide film formed on the channel layers 140 may be removed. Through the cleaning process, the back gate dielectric layer 122 and the lower insulating pattern 130 may be partially etched and side surfaces (of upper regions) of the channel layers 140 may be exposed.

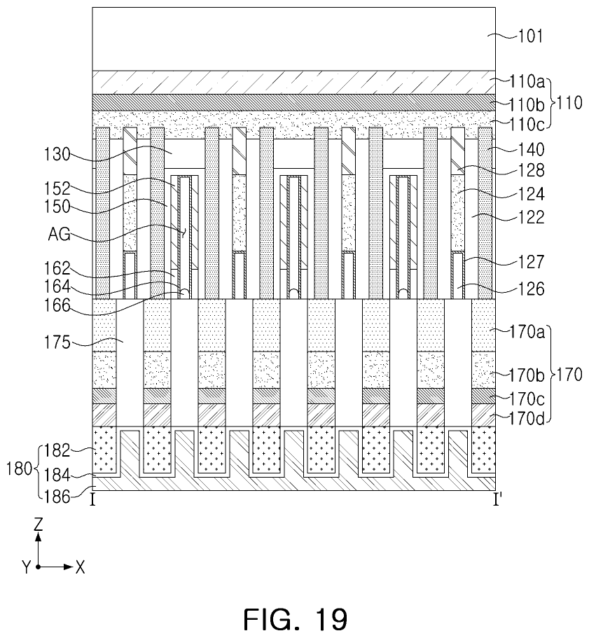

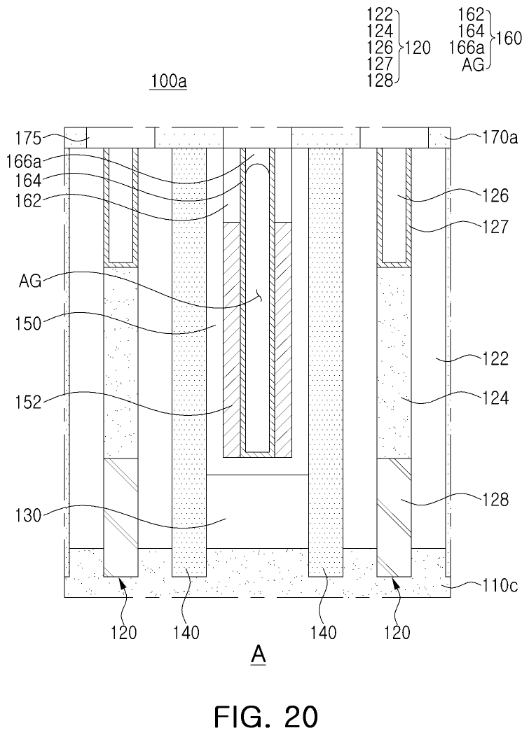

Referring to FIGS. 2 and 19, the bit line structure 110 and the lower insulating layer 101 may be formed on the channel layers 140 so that the semiconductor device 100 may be manufactured. The bit line structure 110 may include a third conductive pattern 110c, a second conductive pattern 110b, and a first conductive pattern 110a, sequentially stacked on the channel layers 140.

In an example embodiment, a peripheral circuit structure including peripheral circuit elements electrically connected to at least one of the bit line structures 110 may be disposed on the lower insulating layer 101.

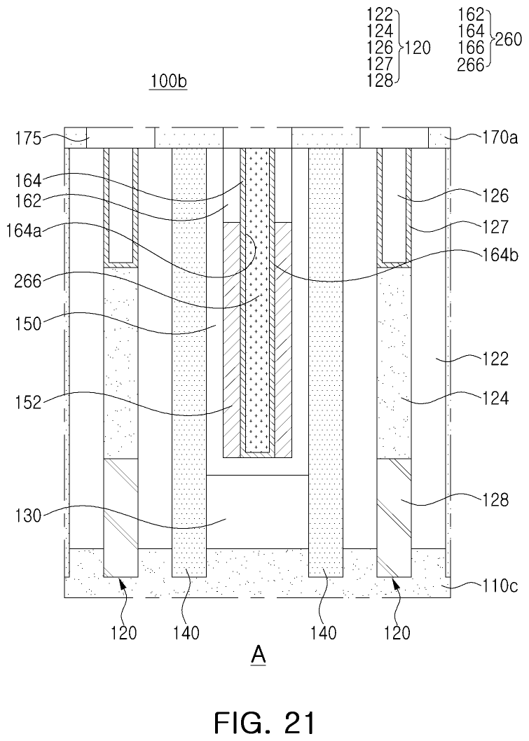

FIGS. 20 to 25 are cross-sectional views of semiconductor devices according to example embodiments.

Referring to FIG. 20, an insulating structure 160 of a semiconductor device 100a may include a gate capping layer 162, a capping pattern 166a, an air gap AG, and an insulating liner 164. The capping pattern 166a and the insulating liner 164 may define the air gap AG. In an example embodiment, a lower surface of the capping pattern 166a defining an upper limit of the air gap AG may be concave. The capping pattern 166a may be concave toward the upper insulating patterns 175 in the Z-direction.

Referring to FIG. 21, an insulating structure 260 of a semiconductor device 100b may include a gate capping layer 162, an insulating liner 164, a capping pattern 166, and a low-κ dielectric material 266 disposed on the insulating liner 164. For example, the low-κ dielectric material 266 may be disposed on an inner surface 164a (and/or an outer surface 164b) of the insulating liner 164. In an example embodiment, the low-κ dielectric material 266 may be disposed in the core region, and completely fill a space between the insulating liners 164 in the X-direction. The low-κ dielectric material 266 may be formed between the word lines 152 during the process of forming the capping material layer 166p described with reference to FIG. 12. An upper surface of the low-κ dielectric material 266 may be coplanar with an upper surface of the insulating liner 164 and an upper surface of the gate capping layer 162.

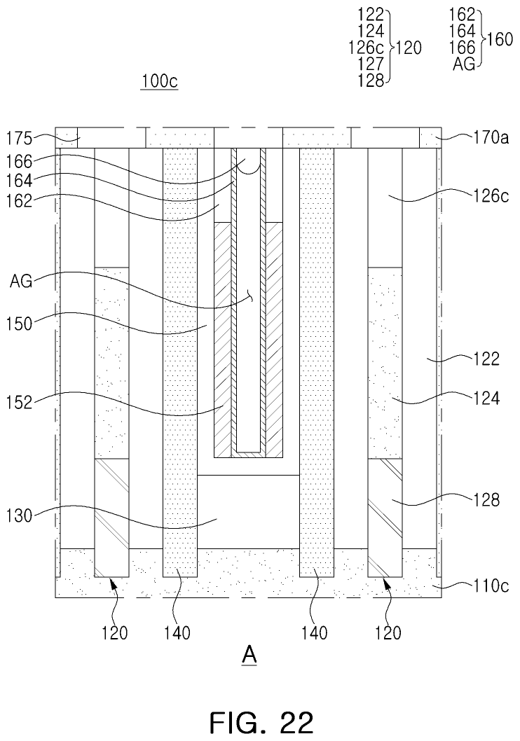

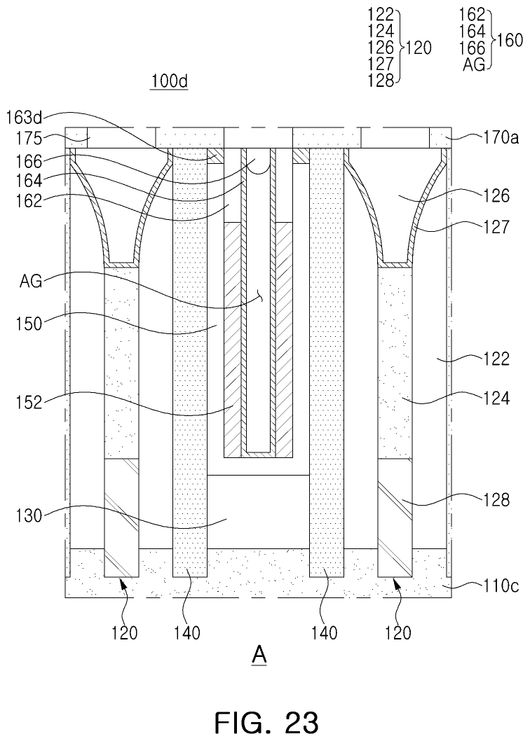

Referring to FIG. 22, a back gate structure 120 of a semiconductor device 100c may include a back gate dielectric layer, a back gate electrode 124, an upper capping layer 126c on the back gate electrode 124, and the lower capping layer 128. In an example embodiment, unlike the embodiment shown in FIG. 3, a back gate liner 127 may be omitted. For example, the upper capping layer 126c may be on (may contact) an upper surface of the back gate electrode 124 and a side surface of the back gate dielectric layer 122 (without the back gate liner 127 therebetween).

In the wet etching process described with reference to FIG. 10, a preliminary capping layer 126p may include a material having etch selectivity with the sacrificial layer 160p and may not be removed. For example, the preliminary capping layer 126p may include silicon nitride. In the process of forming a liner material layer 164p described with reference to FIG. 11, the liner material layer 164p may be formed on the preliminary capping layer 126p and may not contact the back gate electrode 124. The preliminary capping layer 126p after the etch-back process described with reference to FIG. 13 may be referred to as an upper capping layer 126c.

Referring to FIG. 23, a back gate structure 120 of a semiconductor device 100d may include a back gate dielectric layer 122, a back gate electrode 124, an upper capping layer 126, a back gate liner 127, and a lower capping layer 128. In the wet etching process described with reference to FIG. 10, at least one of an upper portion of the back gate dielectric layer 122 and an upper portion of the gate dielectric layer 150 may be etched.

In an example embodiment, a horizontal width (in the X-direction) of the back gate dielectric layer 122 may decrease upwardly. An upper end of the back gate dielectric layer 122 may be located on a level lower than an upper surface of the channel layer 140. A horizontal width (in the X-direction) of the upper capping layer 126 may decrease downwardly. A portion of the upper capping layer 126 may overlap the back gate dielectric layer 122 in a vertical direction (in the Z-direction). A portion of the back gate liner 127 may be in contact with the channel layer 140.

A semiconductor device 100d may further include an insulating layer 163d disposed on (e.g., in contact with) a side surface of the insulating structure 160 and an upper surface (e.g., the uppermost surface) of the gate dielectric layer 150. The insulating layer 163d may contact a side surface of the channel layer 140 and a side surface of the gate capping layer 162. The insulating layer 163d may also contact an upper surface of the gate dielectric layer 150. The insulating layer 163d may include, for example, silicon nitride.

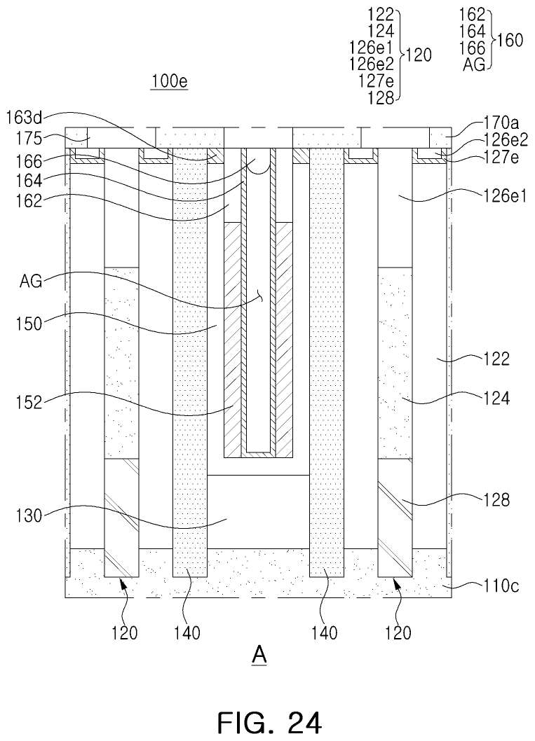

Referring to FIG. 24, a back gate structure 120 of a semiconductor device 100e may include a back gate dielectric layer 122, a back gate electrode 124, a first upper capping layer 126e1 on the back gate electrode 124, second upper capping layers 126e2 disposed both side surfaces (opposite side surfaces in the X-direction) of the first upper capping layer 126e1, back gate liners 127e on (e.g., covering) side surfaces and lower surfaces of the second upper capping layers 126e2, and a lower capping layer 128. The back gate liners 127e may contact a side surface of the first upper capping layer 126e1. The first upper capping layer 126e1, the second upper capping layers 126e2, and the back gate liners 127e may include, for example, silicon nitride. The semiconductor device 100e may include the insulating layer 163d that is included in the semiconductor device 100d in FIG. 23.

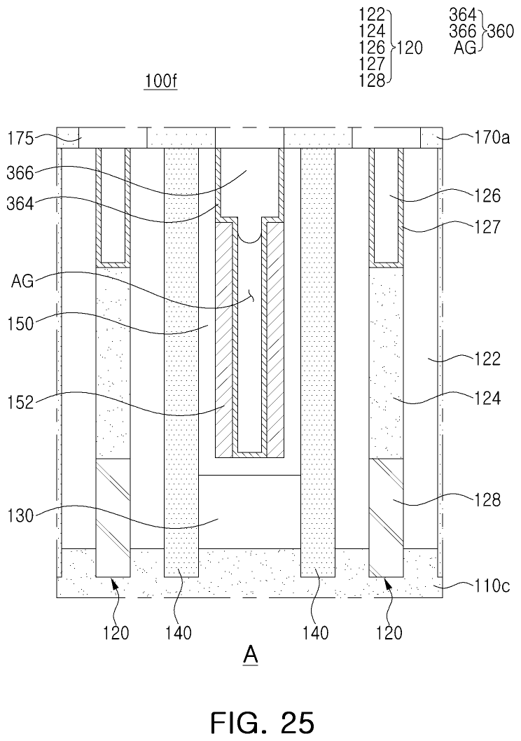

Referring to FIG. 25, an insulating structure 160 of a semiconductor device 100f may include a capping pattern 366, an insulating liner 364, and an air gap AG. In an example embodiment, unlike the embodiment shown in FIG. 3, a gate capping layer 162 may be omitted. For example, the gate capping layer 162 may include the same material as the sacrificial layer 160p, and in the wet etching process described with reference to FIG. 10, the gate capping layer 162 can be removed together with the sacrificial layer 160p.

The insulating liner 364 may be in contact with upper and side surfaces of the word lines 152, and a side surface of the gate dielectric layer 150. A portion of the capping pattern 366 may overlap the word lines 152 in a vertical direction (in the Z-direction). A lower end of the capping pattern 366 may be located on a level lower than the upper surfaces of the word lines 152. The capping pattern 366 may have a horizontal width (in the X-direction) greater than the horizontal width (in the X-direction) of the air gap AG.

As set forth above, according to example embodiments of the technical idea of the present inventive concept, since an air gap or a low-κ dielectric material is disposed between word lines, coupling noise between adjacent word lines may be reduced or prevented. Accordingly, it is possible to prevent leakage current from occurring in an unselected transistor when a semiconductor device is operating.

The various and advantageous advantages and effects of the present inventive concept are not limited to the above description, and may be more easily understood in the course of describing the specific embodiments of the present inventive concept.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a bit line structure;
back gate structures on the bit line structure;
a first channel layer and a second channel layer between the back gate structures in a first direction, wherein the first channel layer and the second channel layer extend in a second direction;
a first word line and a second word line between the first channel layer and the second channel layer in the first direction, wherein the first word line is adjacent to the first channel layer, and the second word line is adjacent to the second channel layer; and
an insulating structure on a side surface of the first word line, a side surface of the second word line, an upper surface of the first word line, and an upper surface of the second word line,
wherein the insulating structure includes
a core region between the first word line and the second word line in the first direction; and
an insulating liner between the core region and the first word line in the first direction and between the core region and the second word line in the first direction,
wherein the side surface of the first word line and the side surface of the second word line face each other in the first direction,
wherein the insulating liner extends to a level higher than those of the first word line and the second word line,
wherein the first direction is parallel with a lower surface of the bit line structure, and
wherein the second direction is perpendicular to the lower surface of the bit line structure.

2. The semiconductor device of claim 1, wherein the insulating structure further comprises a first gate capping layer on the upper surface of the first word line and a second gate capping layer on the upper surface of the second word line, and
wherein the insulating liner is between the core region and the first gate capping layer in the first direction and between the core region and the second gate capping layer in the first direction.

3. The semiconductor device of claim 2, wherein the insulating structure further comprises a capping pattern on the core region, and
wherein the insulating liner is between the capping pattern and the first gate capping layer in the first direction and is between the capping pattern and the second gate capping layer in the first direction.

4. The semiconductor device of claim 3, wherein a lower surface of the capping pattern is convex toward the core region.

5. The semiconductor device of claim 1, wherein the core region includes an air gap.

6. The semiconductor device of claim 1, further comprising:
a gate dielectric layer below a lower surface of the insulating structure,
wherein the gate dielectric layer is between the first word line and the first channel layer in the first direction and between the second word line and the second channel layer in the first direction, and
wherein the insulating liner is between the core region and the gate dielectric layer in the second direction.

7. The semiconductor device of claim 1, wherein each of the back gate structures comprises a back gate electrode, an upper capping layer on the back gate electrode, and a back gate liner on a lower surface and a side surface of the upper capping layer.

8. The semiconductor device of claim 7, wherein the back gate liner comprises a same material as that of the insulating liner.

9. The semiconductor device of claim 7, wherein a horizontal width of the upper capping layer in the first direction decreases as the upper capping layer extends toward the back gate electrode in the second direction.

10. The semiconductor device of claim 9, wherein each of the back gate structures further comprises a back gate dielectric layer on a side surface of the back gate electrode and the side surface of the upper capping layer, and
wherein a horizontal width of the back gate dielectric layer in the first direction decreases as the back gate dielectric layer extends farther from the lower surface of the bit line structure.

11. The semiconductor device of claim 1, wherein the insulating structure further comprises a capping pattern on the core region, and
wherein a lower surface of the capping pattern is concave in the second direction.

12. The semiconductor device of claim 1, wherein the core region comprises a low-κ dielectric material having a dielectric constant lower than that of silicon oxide.

13. The semiconductor device of claim 1, wherein each of the back gate structures comprises a back gate electrode, a first upper capping layer on the back gate electrode, a back gate dielectric layer on a side surface of the back gate electrode, and second upper capping layers on opposite sides of the first upper capping layer in the first direction.

14. The semiconductor device of claim 1, wherein the insulating structure further comprises a capping pattern on the core region,
wherein a portion of the capping pattern overlaps the first word line and the second word line in the second direction,
wherein a lower end of the capping pattern is closer than the upper surface of the first word line and the upper surface of the second word line to the lower surface of the bit line structure in the second direction, and
wherein the insulating structure is in contact with the side surface of the first word line, the side surface of the second word line, the upper surface of the first word line, and the upper surface of the second word line.

15. The semiconductor device of claim 14, wherein the insulating liner is on the upper surface of the first word line and the upper surface of the second word line.

16. A semiconductor device, comprising:
a bit line structure;
a channel layer on the bit line structure, wherein the channel layer extends in a first direction;
a back gate structure facing a first side surface of the channel layer in a second direction;
a word line facing a second side surface of the channel layer that is opposite to the first side surface of the channel layer in the second direction;
a gate dielectric layer between the channel layer and the word line in the second direction; and
an insulating structure on the word line,
wherein the gate dielectric layer includes a vertical portion in contact with a first side surface of the word line and a side surface of the insulating structure, and a horizontal portion in contact with a lower surface of the word line and a lower surface of the insulating structure,
wherein the insulating structure includes
a core region spaced apart from the word line; and
an insulating liner between the core region and a second side surface of the word line in the second direction, and extending between the horizontal portion and the core region in the first direction,
wherein the first side surface of the word line is opposite to the second side surface of the word line in the second direction,
wherein the first direction is perpendicular to a lower surface of the bit line structure, and
wherein the second direction is parallel with the lower surface of the bit line structure.

17. The semiconductor device of claim 16, wherein the insulating structure further comprises a capping pattern in contact with an upper region of an inner surface of the insulating liner, and
wherein the core region includes an air gap.

18. The semiconductor device of claim 16, wherein the back gate structure further comprises a back gate electrode and a back gate dielectric layer between the back gate electrode and the channel layer in the second direction, and
wherein a lower surface of the back gate dielectric layer is farther than a lower surface of the channel layer from the lower surface of the bit line structure.

19. The semiconductor device of claim 16, further comprising:
an insulating pattern between the bit line structure and the gate dielectric layer in the first direction.

20. A semiconductor device, comprising:
a bit line structure;
back gate structures on the bit line structure;
a first channel layer and a second channel layer between the back gate structures in a first direction, wherein the first channel layer and the second channel layer extend in a second direction;
a first word line and a second word line between the first channel layer and the second channel layer in the first direction, wherein the first word line is adjacent to the first channel layer, and the second word line is adjacent to the second channel layer;
an insulating structure in contact with a side surface of the first word line, a side surface of the second word line, an upper surface of the first word line, and an upper surface of the second word line;
a gate dielectric layer between the first channel layer and the first word line in the first direction, between the first channel layer and a first upper region of the insulating structure in the first direction, between the second channel layer and the second word line in the first direction, and between the second channel layer and a second upper region of the insulating structure in the first direction;
contact patterns electrically connected to the first channel layer and the second channel layer; and
an information storage structure on the contact patterns,
wherein the insulating structure includes a core region spaced apart from the first word line and second word line; and
an insulating liner between the side surface of the first word line and the core region and between the side surface of the second word line and the core region, and extending to a level higher than those of the first word line and the second word line,
wherein the core region has a dielectric constant lower than that of silicon oxide,
wherein the first upper region of the insulating structure is on the first word line,
wherein the second upper region of the insulating structure is on the second word line,
wherein the side surface of the first word line and the side surface of the second word line face each other in the first direction,
wherein the first direction is parallel with a lower surface of the bit line structure, and
wherein the second direction is perpendicular to the lower surface of the bit line structure.
